(19) United States
(12) Patent Application Publication
(10) Pub. No.: US 2006/0012031 A1
(43) Pub. Date: Jan. 19, 2006

(54) Heat dissipation device for integrated circuits

(76) Inventor: Elstan Anthony Fernandez, Singapore (SG)

Correspondence Address: SLATER & MATSIL LLP, 17950 PRESTON ROAD, SUITE 1000, DALLAS, TX, 75252, US

(21) Appl. No.: 10/523,257

(22) PCT Filed: Jul. 30, 2002
(86) PCT No.: PCT/SG02/00170

§ 371 Date: Jan. 27, 2005

(51) Int. Cl. H01L 23/10

(52) U.S. Cl. 257/706

(57) ABSTRACT

An integrated circuit (27, 67) is packaged by mounting it onto a substrate (11, 55) with a heat conductive plate (1, 41) interposed between the integrated circuit (27, 67) and the substrate (11, 55). The plate (1, 41) has portions (5, 7, 9) extending laterally out from under the integrated circuit, and these portions conduct away heat generated by the integrated circuit (27, 67). The plate (1, 41) may be connected to ground, and be connected by wire bonding to pads of the integrated circuit (27, 67) which are to be grounded. In one arrangement, the plate (1) may be located above a second integrated circuit such as a flipchip (22). In another arrangement, a plurality of integrated circuits (67) may be connected to the substrate (55) via the plate (41), and the substrate (55) and plate (41) singulated together to form a plurality of packages.

### FIELD OF THE INVENTION

The present invention relates to a method of forming semiconductor packages, and to packages which are the result of the method.

### BACKGROUND OF THE INVENTION

Several ways are known of mounting a semiconductor integrated circuit (die) onto a surface of a substrate. This process is known as “packaging”. The substrate has electrical connections leading out of the substrate (e.g. through the material of the substrate, through “via holes”) for connection to other components.

For example, in the case of an integrated circuit having input/output die pads, it is well known to mount the integrated circuit onto a substrate having corresponding electrical pads which are electrically connected out of the substrate (e.g. by via holes). Wire bonding is used to connect the pads of the integrated circuit to respective pads of the substrate, and then the die and wire bonds are encased in resin. Optionally, a number of integrated circuits can be mounted on a single substrate in this way, and then the substrate “singulated”, i.e. cut to provide a number of individual packaged devices each containing one (or more) of the integrated circuits.

In a second example, a “flipchip” is an integrated circuit where the input/output connections are provided as electrically conductive protrusions on one of its surfaces. The flipchip is mounted in a cavity formed on the upper surface of the integrated circuit, with the protrusions facing downwardly. The protrusions are received into openings in the substrate (i.e. in the surface at the bottom of the cavity). Each opening includes electrically conductive material which contacts the protrusions, and the openings are in turn are electrically connected out of the substrate (e.g. by via holes). Again, once the flipchip is in position, it is encased in protective resin, which may fill the cavity

In some arrangements, it is known to provide a flipchip encased as described in the preceding paragraph, and a second integrated circuit mounted directly above it. The second integrated circuit is connected by wire bonding to pads on the upper surface of the substrate laterally outward of the cavity. Then the second integrated circuit is encased in resin.

One of the main limitations on integrated circuit design is heat generation within the integrated circuit, since if the integrated circuit overheats, it may fail operate properly. It would therefore be advantageous to provide ways of mounting integrated circuits on substrates such that heat is more easily transmitted from them.

### SUMMARY OF THE INVENTION

The present invention aims to provide a new and useful semiconductor packages (that is, substrates incorporating at least one integrated circuit mounted thereon), and methods for mounting integrated circuits on substrates.

In general terms, the present invention proposes that an integrated circuit is mounted on a substrate via a heat conductive plate interposed between the integrated circuit and the substrate and having at least one portion extending laterally out from under the integrated circuit.

The integrated circuit is generally of the type having pads for connection to the substrate by wire bonding. Following the wire bonding, the integrated circuit and wire bonds are encased in resin, but the plate preferably extends out of the resin, so that heat generated in the integrated circuit is conducted out of the resin.

The plate is preferably shaped so as to not to block the areas at which the pads of the integrated circuit are connected to the substrate. For example, the plate may extend out from under the integrated circuit in directions which are diagonal relative to the overall square or rectangular circumference of the integrated circuit, since the integrated circuit will not generally require wire bonding to the substrate in these directions.

Preferably, the plate is grounded. In this case, it may supplement or even replace the ground ring (that is, the device which in many known arrangements is provided electrically connected to ground and also to the pads of the integrated circuit which are to be grounded). Some or all of these ground pads may instead be connected to the plate. If any ground ring is provided, it may be electrically connected to the plate. In the case that certain pads of the integrated circuit are to be electrically connected to ground, then it is desirable that the plate should extend out from under the integrated circuit in the direction towards these pads.

The plate may have portions of increased thickness laterally outward from the integrated circuit. For example, there may be a rim extending in transversely to the substrate surface. Optionally, a further heat-transmissive element may be connected to the plate after the application of the resin, for example to the rim.

The present device may be used in arrangements which include a flipchip. In this case, the plate may be mounted over a flipchip (preferably directly onto the upper surface of a flipchip which has not been encased in resin, or in alternative arrangements onto the upper surface of resin encasing the flipchip).

In cases when a plurality of integrated circuits are mounted onto the same substrate, a single heat conductive plate is preferably provided extending under more than one of the integrated circuits (e.g. preferably under all the integrated circuits), and this plate too is cut when the substrate is singulated.

### BRIEF DESCRIPTION OF THE FIGURES

Two embodiments of the invention will now be described in detail for the sake of example only, with reference to the following figures in which:

FIG. 1 shows in top view a heatspreader plate used in a first embodiment;

FIG. 2 shows in an assembled structure which is the first embodiment of the invention and includes the plate of FIG. 1;

FIG. 3 is an exploded perspective view of the arrangement of FIG. 2;

FIG. 4, which is composed of FIGS. 4(a) and 4(b), illustrates the mounting of a heatspreader plate in the second embodiment of the invention;

FIG. 5 shows in an assembled structure which is the second embodiment of the invention and includes the plate of FIG. 4(a); and

FIG. 6 is an exploded perspective view of the arrangement of FIG. 5.

### DETAILED DESCRIPTION OF THE EMBODIMENTS

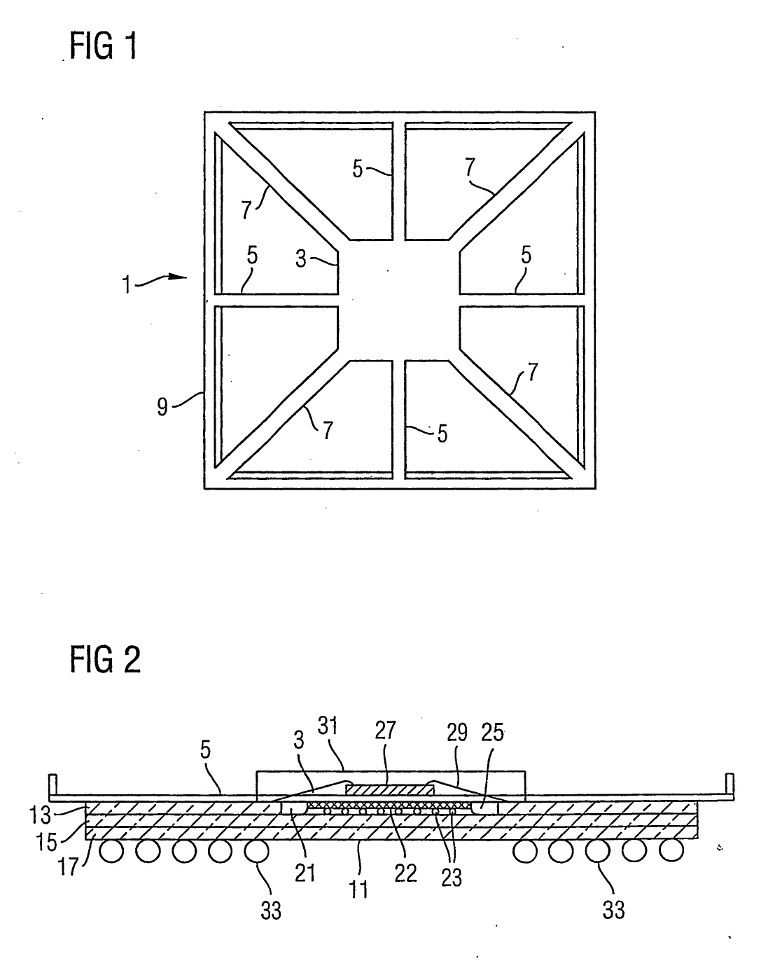

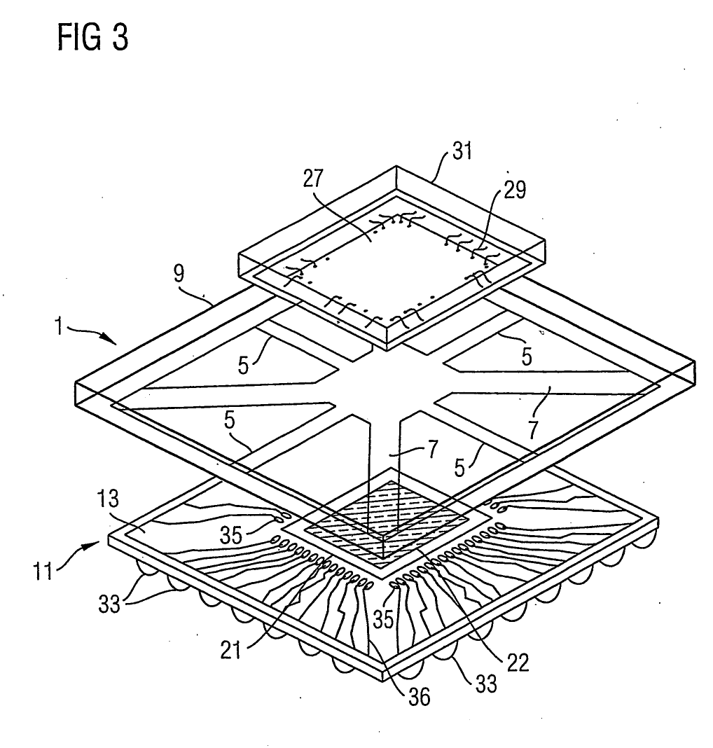

A first embodiment of the invention is shown in FIGS. 1-3. Referring to FIG. 1, the heatspreader plate 1 is composed of a central portion 3, four lateral arms 5, four diagonal arms 7 and a rim portion 9. As seen (for example in FIG. 3) the rim portion 9 includes a rim extending upwardly, so that the rim portion 9 is thicker in the height direction than the other portions of the plate 1. The plate 1 is preferably formed of metal, such as an aluminium/copper alloy.

Turning to FIG. 2, a structure according to the invention is shown in cross section. The plate 1 is mounted on a substrate 11 having three layers 13, 15, 17. The upper layer 13 contains a square central aperture so that the substrate 11 includes a cavity 21. A flipchip 22 is located in the cavity 21 and connected to the bottom surface of the cavity 21 by protrusions 23. These protrusions are surrounded by an underfill layer 25, which may be of resin. The central portion 3 of the device 1 is sandwiched between the flipchip 22 and the die 27, and preferably connected to each by a heat-conductive glue. The pads on the die 27 are connected by wire bonds 29 to corresponding pads on the upper surface of layer 13 laterally outward from the cavity 21. The die 27 is encased in resin 31. The undersurface of the substrate 11 is provided with eutectic solder balls 33. In this cross section two of the diagonal arms 7 are visible laterally outward from the resin 31. Since the plate 1 contacts both the die 27 and the flipchip 22, it is able to receive heat generated within each and transmit it out of the structure laterally (i.e. in the sideways direction in FIG. 2). Note that the plate 1 preferably extends laterally outside the resin 31 in all four lateral directions.

Turning to FIG. 3 the structure of FIG. 2 is shown in an exploded view, with the plate 1 taking the form shown in FIG. 1. In this view the pads 35 on the upper surface of the layer 13 are visible, with their corresponding via holes 36. Note that when the plate 1 rests on the substrate 11, the diagonal arms 7 tend not to cover any of these pads 35. The lateral arms 5 do however cover some of the pads 5. For this reason the lateral arms 5 may be omitted. Alternatively, if the lateral arms 5 are included, the die 27 may be designed such that its pads which correspond in position to the position of these arms (i.e. its pads at the centre of its sides) are the pads which are to be connected to ground. In this case, these pads may be connected directly to the plate 1 rather than to pads on the substrate 11.

Note that it is preferred that the rim portion 9 of the device 1 (i.e. the portion of the device 1 which entirely encircles the die 27) is laterally outward of the edge of the substrate 11. This is because the upper surface of the substrate 11 may include a number of areas (such as via holes) having a function which would be disrupted if they were connected to ground. Since the rim 9 is laterally outward of the substrate, the area at which the substrate 11 and plate 1 contact each other is minimised.

The order of steps used to form the arrangement of FIG. 3 is as follows. Firstly, after bumping, the flipchip 22 is located on the substrate 11. Then, the underfill layer 25 is applied. Then the plate 1 is attached to the flipchip 22 by heat-conductive glue. Then the die 27 is attached to the plate 1 by heat-conductive glue. To avoid pressure of the die 27 upon the flipchip 22 the flipchip 22 should be larger in area than the die 27, and this feature also has advantages in terms of the IO count of the two devices. Then the wire-bonding is done to connect the substrate 11 and the die 27. Once wirebonding is completed, the resin 31 is applied. As shown in FIGS. 2 and 3 the resin 31 is only applied to a central region of the substrate 11 (using a mould, not shown), however the plate 1 can itself constitute the mould and in this case the resin might extend laterally as far as the rim 9. Alternatively, another rim might be formed on the plate 1 laterally inward of the rim 9 to provide the sides of a mould in which the resin 31 could be formed. Curing of the resin 31 is performed only once to avoid die crack. The marking is done to complete the packaging.

Optionally, further heat dissipative devices may be attached to the plate 1 (at this stage, or earlier) to aid the transmission of head out of the plate 1.

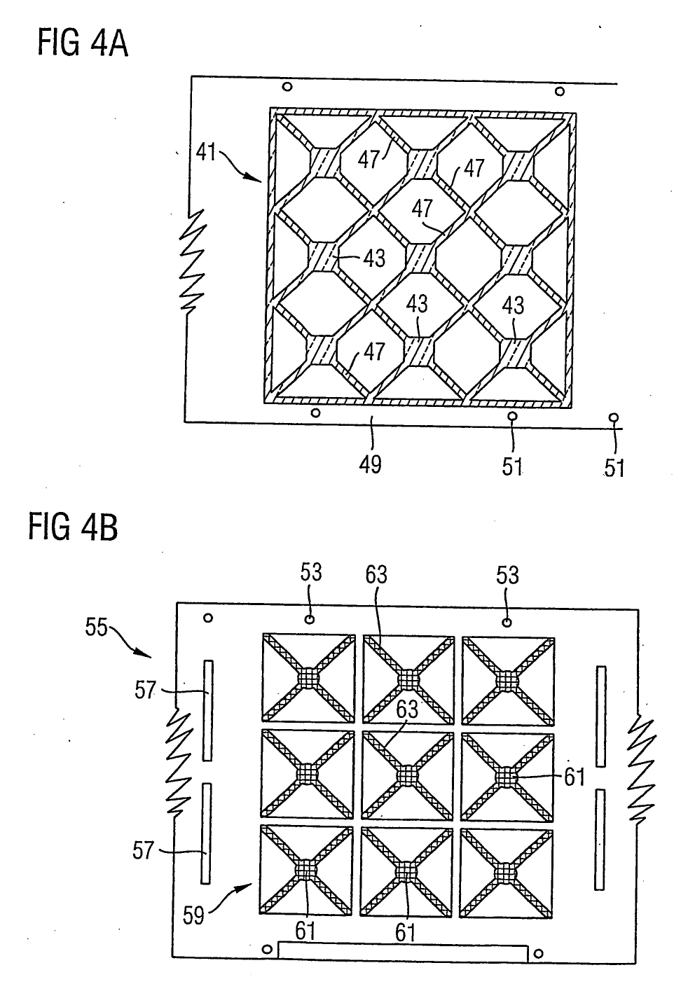

The second embodiment of the invention is shown with reference to FIGS. 4 to 6. The second embodiment relates to a LFBGAS (low profile ball grid array package) with a fine ball pitch (0.5, 0.65 or 1.00 mm). Such BGA packages, delivering higher performance and thermal dissipation, are shrinking in size, so that packaging such silicon dies in an increasing challenge.

The headspreader plate shown in FIG. 4(a) is an aluminium/copper alloy. It is provided as a matrix 41 having central portions 43 for location under integrated circuits and diagonal arm portions 47. It is provided with a strip 49 including holes 51 for location onto holes 53 provided on a substrate strip. The substrate 55 is shown in top view in FIG. 4(b). It has slots 57, and is provided with a heat-conductive adhesive 59 located in the pattern shown in FIG. 4(b), having regions 61 onto which the central portions 43 of the matrix 41 are located. It further has regions 63 onto which the arm portions 47 of the matrix 41 are located.

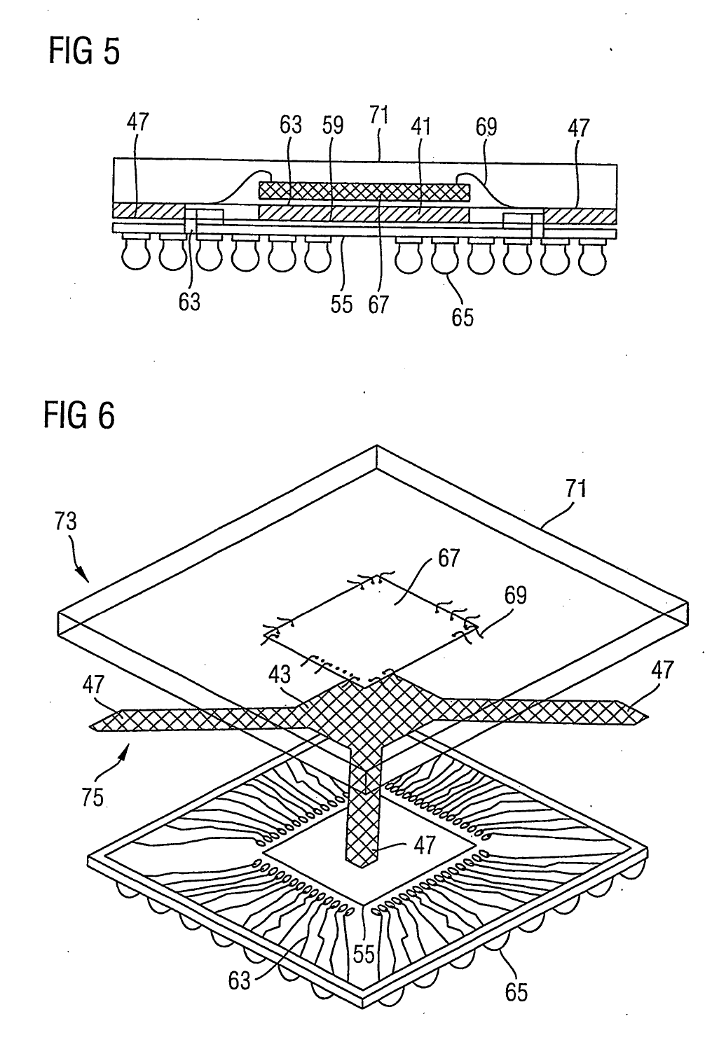

The structure of a portion of the arrangement after the matrix 41 is attached to the substrate 55 is shown in cross-section in FIG. 5. The substrate 55 is provided with via holes 63 and eutetic solder balls 65 connected to the substrate 55 by a copper connection. The substrate 55 is connected to the matrix 41 by the heat-conductive adhesive 59. Subsequently, the die 67 is connected to the central portion 43 of the matrix 41 using the same heat conductive adhesive.

Wire-bonds 69 are produced. Optionally, ground pads at the corners of the die can be directly connected to the diagonal arms 47. Then a resin 71 is formed encasing the die 67 and the wire bonds 69.

Singulation is now performed, separating the structure of FIG. 5 into separate units 73 each including a single die 67. The result is shown, in an exploded view, in FIG. 6. Note that due to the singulation process, the matrix 41 has been sliced into a section 75 within each unit 73 which includes a single central region 43 and four diagonal arms 47 (each of which is half as long as the diagonal arms of FIG. 4(a)). By the section 75 of the matrix 41 heat generated by the die 67 is transmitted out of the package at its corners. The section 75 may be connected to ground.

Although only two embodiments of the invention have been described in detail, many variations of them are possible within the scope of the invention as will be clear to a skilled reader.

1. A semiconductor package including
a substrate,
an integrated circuit mounted on the substrate, and
a heat conductive plate having a portion interposed between the integrated circuit and the substrate, the heat conductive plate being heat-conductively connected to the integrated circuit and having at least one portion extending laterally out from between the integrated circuit and the substrate.

2. A semiconductor package according to claim 1 in which the integrated circuit is encased in resin, the plate extending out of the resin, whereby heat generated in the integrated circuit is conducted out of the resin.

3. A semiconductor package according to claim 1 in which the plate includes a central region disposed between the substrate and the integrated circuit and arms extending laterally from the central region with openings between them, the integrated circuit being connected to the substrate by wire bonding in the openings.

4. A semiconductor package according to claim 3 wherein the integrated circuit has a substantially square or rectangular profile and where at least one of the arms extends in a direction which is diagonal relative to the square or rectangular profile of the integrated circuit.

5. A semiconductor package according to claim 1 in which the plate is grounded and electrically connected to at least one ground input of the integrated circuit.

6. A semiconductor package according to claim 1 in which the plate includes at least one portion of increased thickness laterally outward from the integrated circuit.

7. A semiconductor package according to claim 1 and further comprising a second integrated circuit disposed between the plate and the substrate.

8. A semiconductor package according to claim 7 in which the plate is in heat-conductive contact to the second integrated circuit, whereby heat generated by the second integrated circuit is conducted away from the second integrated circuit by the plate.

9. A semiconductor package according to claim 7 in which the second integrated circuit is a flipchip.

10. A method of forming a semiconductor package the method comprising:
securing a heat-conductive plate over a substrate, and
mounting at least one integrated circuit over the heat-conductive plate with a heat-conductive connection therebetween, the heat conductive plate having at least one portion extending laterally out from between the integrated circuit and the substrate.

11. A method according to claim 10 in which after mounting the integrated circuit to the heat-conductive plate, the integrated circuit is embedded in resin, the heat-conductive plate extending laterally out of the resin.

12. A method according to claim 10 in which, prior to securing the heat-conductive plate to the substrate a second integrated circuit is mounted on the substrate, the heat-conductive plate being secured to the substrate with the second integrated circuit between a portion of the plate and the substrate.

13. A method according to claim 10, in which there are a plurality of said integrated circuits, the plate extending between each of the integrated circuits and the substrate, the method further including a singulation step in which the substrate and plate are cut to produce a plurality of semiconductor packages each including at least one of the integrated circuits.

14. A packaged semiconductor device comprising:
a substrate including a plurality of contact regions on an upper surface;
a heat conductive plate mounted over the substrate, the heat conductive plate comprising a central portion and a plurality of arms extending outwardly from the central portion;
an integrated circuit having a bottom surface mounted over the central portion of the heat conductive plate; and
a plurality of electrical connections between an upper surface of the integrated circuit and the contact regions of the substrate, the electrical connections extending between adjacent ones of the arms of the heat conductive plate.

15. The packaged semiconductor device of claim 14 wherein the heat conductive plate further comprises a rim portion that surrounds the central portion and is thermally connected to the central portion by the plurality of arms.

16. The packaged semiconductor device of claim 15 wherein the heat conductive plate includes four diagonal arms, each diagonal arm extending outwardly from a corner of the central portion to the rim portion.

17. The packaged semiconductor device of claim 16 wherein the heat conductive plate further includes four lateral arms, each lateral arm extending outwardly from a side surface of the central portion of the plate to the rim portion.

18. The packaged semiconductor device of claim 14 wherein the electrical connections comprise wire bonds.

19. The packaged semiconductor device of claim 14 and further comprising a plurality of balls disposed on a lower surface of the substrate, each of the balls electrically coupled to a respective one of the contact regions.

20. The packaged semiconductor device of claim 14 wherein the central portion of the heat conductive plate is affixed to the integrated circuit by heat-conductive glue and wherein the central portion of the heat conductive plate is affixed to the substrate by heat-conductive glue.
